(19) United States
(12) Patent Application Publication
(10) Pub. No.: US 2001/0050420 A1
(43) Pub. Date: Dec. 13, 2001

(54) LEADFRAME HAVING JOINED INTERNAL LEAD

(76) Inventor: TE-SHENG YANG, TAIPEI (TW)

Correspondence Address: J.C. PATENTS INC., 4 Venture, Suite 250, Irvine, CA, 92618, US

(21) Appl. No.: 09/231,538

(22) Filed: Jan. 14, 1999

(30) Foreign Application Priority Data
Nov. 27, 1998 (TW) 87119707

(51) Int. Cl. H01L 23/495

(52) U.S. Cl. 257/676

(57) ABSTRACT

A type of leadframe having a joined internal lead. A leadframe includes a plurality of adhesion pads and a plurality of leads. The leads are arranged around the adhesion pads. The adhesion pads are formed by joining some extended leads. The adhesion leads replace the conventional die pad to support and attach a chip.

### BACKGROUND OF THE INVENTION

1. Field of the Invention

The present invention relates to a type of leadframe. More particularly, the present invention relates to a type of leadframe having a joined internal lead.

2. Description of the Related Art

In general, the process of manufacturing semiconductor devices includes three stages: the process of fabricating a wafer, the process of fabricating devices on the wafer and the process of packaging devices. In the process of packaging devices, a leadframe is used as a base for attaching a chip.

FIG. 1 is a schematic, top view of a conventional leadframe.

Referring to FIG. 1, a conventional leadframe 10 is generally divided into two parts. One is a flat portion, called a die pad 12, and the other is a plurality of lead portions. Each lead portion is divided into internal lead 14, lead shoulder 16 and external lead 18. A package area 22 is used for packaging a chip. A bonding area 20 positioned in the package area 22 is used for a wire bonding step. Portions of the internal leads 14 located in the bonding area 20 are also called coin lead tips 24. Side rails 26 are used to connect to other leadframes. Pilot holes 28 are for aligning the leadframe 10 during the packaging process. The die pad 12 and side rails 26 are connected by supporting bars 30. Dam bars 32 are used to avoid sealing resin overflow. The side rails 26 and the leads are connected by the dam bars 32.

In some semiconductor packages such as SOP (Small Outline Package) and TSOP (Thin Small Outline Package), coin lead tips 24 are designed to be densely arranged around the die pad 12 in order to meet the wire bonding step requirement. Thus, the supporting bars 30 can only be positioned along the axis of the die pad 12 and the size of the supporting bars 30 is limited. During the molding step, the die pad 12 may be tilted or deflected, i.e. the die pad 12 floats, because the supporting bars 30 are too small to support the die pad 12.

Furthermore, the sealing resin flow on two sides of the die pad is affected by the surface area of the die pad 12. The flow velocity of the sealing resin at two sides of the die pad is also different, so that a pressure difference is caused. The pressure difference deforms the leadframe 10, thus the die pad 12 is exposed in the semiconductor package.

Forming a cavity in the die pad or LOC (Lead On Chip) leadframes are two common ways to overcome the above disadvantages of the conventional semiconductor package in industry.

No die pad is designed in LOC leadframes, and a chip is attached on the extended portions of internal leads. The problem of floating is avoided and the pressure difference caused by the die pad is also decreased. The reliability of the semiconductor package is increased.

Although LOC leadframes overcome the disadvantages of the conventional semiconductor package, LOC leadframes are not suitable for a small size chip or a chip having a high pin count. Because the width of the internal leads and the distance between the internal leads must be all larger than a minimum value, the internal leads are not able to support and attach a chip. The chip attached on a LOC leadframe may be cracked during the wire bonding step because the chip is not supported by a die pad. Furthermore, LOC leadframes are not compatible with conventional manufacturing processes and the conventional design rule of a chip.

### SUMMARY OF THE INVENTION

It is therefore an objective of the present invention to provide a type of leadframe that prevents a die pad from floating.

It is therefore another objective of the present invention to provide a type of leadframe that prevents a chip from cracking in a wire bonding step.

It is therefore yet another objective of the present invention to provide a type of leadframe that increases the reliability of the semiconductor package.

To achieve these and other advantages and in accordance with the purpose of the invention, as embodied and broadly described herein, the invention provides a type of leadframe for attaching a chip. The leadframe includes a plurality of adhesion pads and a plurality of leads. The leads are arranged around the adhesion pads. The adhesion pads are formed by joining some extended leads. The adhesion pads replace the conventional die pad to support and attach a chip.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic, top view of a conventional leadframe;

FIG. 2 is a schematic, top view of a leadframe according to the invention;

FIG. 3A and FIG. 3B are schematic, top views of other leadframes according to the invention; and

FIG. 4 is a schematic, cross-sectional view of a semiconductor package according to the invention.

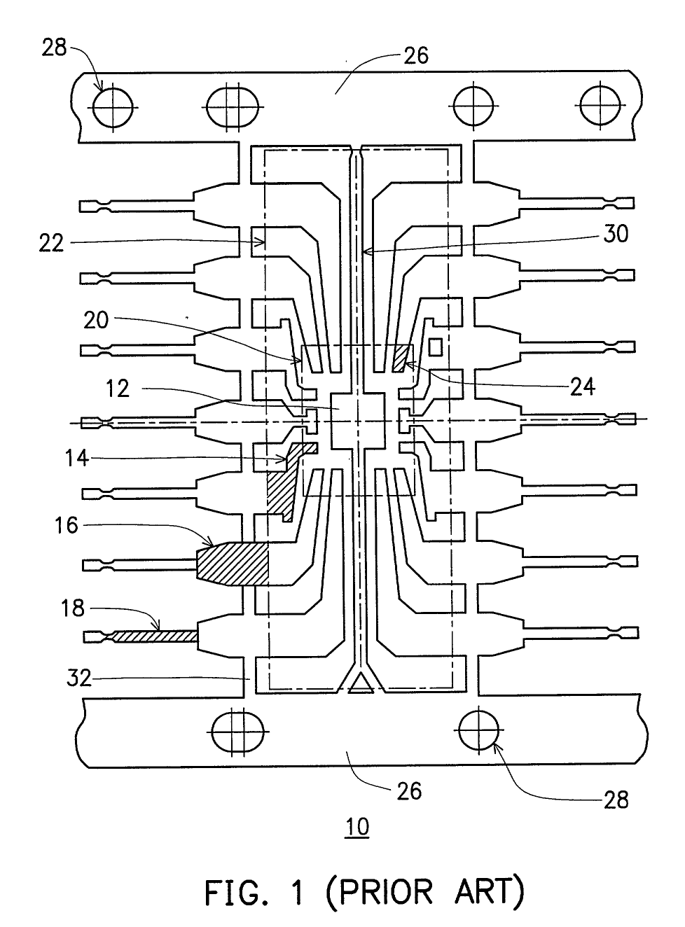

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

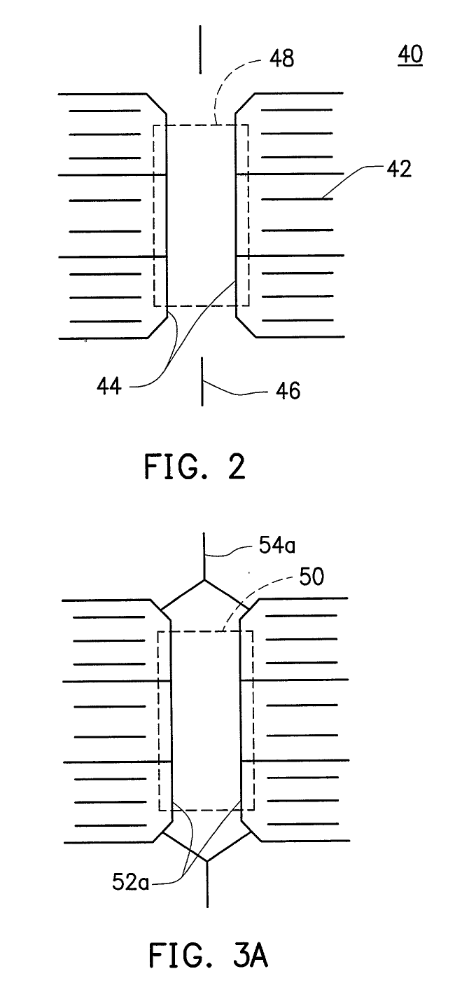

FIG. 2 is a schematic, top view of a leadframe according to the invention.

Referring to FIG. 2, a leadframe 40 is shown, wherein a mounting area 48 is indicated by dashed line. A plurality of leads 42 are arranged around the mounting area 48. A plurality of adhesion pads 44 are positioned beside the mounting area 48. The adhesion pads 44 are formed by joining some extended leads 42. The leads 42 selected to form the adhesion pads 44 all have the same voltage. The adhesion pads 44 may also formed by joining some leads 42 and some no-connected leads. The adhesion pads 44 replace the conventional die pad to support and attach a chip in this invention. Although supporting bars 46 positioned along the axis of the mounting area 48 are not connected to the adhesion pads 44 or the leads 42, the supporting bars 46 are still compatible with the conventional manufacturing process.

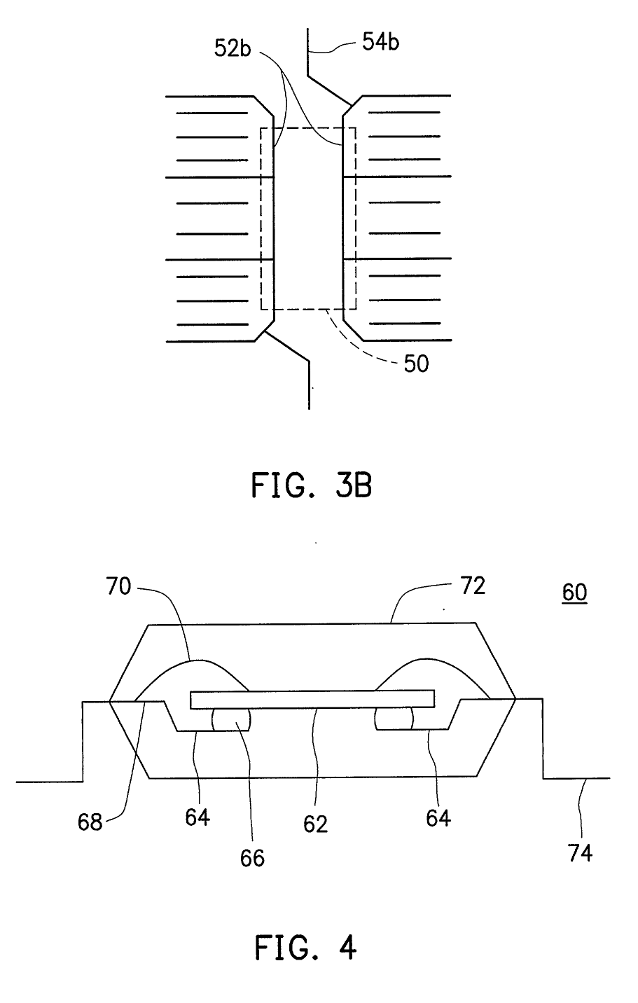

FIG. 3A and FIG. 3B are schematic, top views of other leadframes according to the invention.

Referring to FIG. 3A and FIG. 3B, a mounting area 50 is indicated by a dashed line. A plurality of adhesion pads 52a (shown in FIG. 3A) and a plurality of adhesion pads 52b (shown in FIG. 3B) are positioned beside the mounting area 50. A plurality of supporting bars 54a (shown in FIG. 3A) and a plurality of supporting bars 54b (shown in FIG. 3B) are also positioned along the axis of the mounting area 50. Both ends of each of the adhesion pad 52a are connected to the supporting bars 54a (FIG. 3A). Only one end of each adhesion pad 52b is connected to the supporting bars 5b (FIG. 3B).

FIG. 4 is a schematic, cross-sectional view of a semiconductor package according to the invention.

Referring to FIG. 4, a carrier used in a semiconductor package 60 is the leadframe 40 shown in FIG. 2. A chip 62 is attached to an adhesion pad 64 by using, for example, epoxy, tape or isolation paste as an adhesive, of which isolation paste 66 is preferably used. The adhesion pad 64 is downset in the leadframe 40. An internal lead 68 is electrically coupled with a bonding pad (not shown) through a conducting wire 70 such as gold wire or aluminum wire. The chip 62, the adhesion pad 64, the internal lead 68 and the conducting wire 70 are sealed by an isolation material such as epoxy. An external lead 74 is exposed.

In this invention, the adhesion pad 64 formed by joining some extended internal lead 68 replaces the conventional die pad to support and attach the chip 62, so that the difference between the flow paths caused by the conventional die pad is decreased. The reliability of the semiconductor package is increased.

According to the foregoing, the advantages of the invention include the following:

1. The adhesion pad formed by joining some extended leads replaces the conventional die pad so that it doesn't float like a conventional die pad during the molding step.

2. The adhesion pads are located under the bonding pads. The problem of a chip cracking during a wire bonding step is avoided.

3. The leadframe of this invention increases the reliability of the semiconductor package and is compatible with the conventional manufacturing process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A leadframe having a mounting area, comprising:
a plurality of separate adhesion pads positioned inside the mounting area; and
a plurality of leads positioned around the mounting area.

2. The leadframe of claim 1, wherein the adhesion pads are formed by joining some extended leads.

3. The leadframe of claim 1, wherein the leadframe includes a plurality of supporting bars positioned between the leads, and the adhesion pads are connected to the supporting bars.

4. An semiconductor package comprising;
a chip;
a plurality of adhesion pads attached to the chip, wherein one side of the chip is attached to the adhesion pads;
a plurality of leads arranged around the chip, wherein at least some leads are electrically coupled with the chip;
isolation material sealing the chip, the adhesion pads and portions of the leads.

5. The package of claim 4, wherein the adhesion pads are formed by joining some extended leads.

6. The package of claim 4, wherein the semiconductor package includes a plurality of supporting bars positioned between the leads, and the adhesion pads are connected to the supporting bars.

7. The package of claim 4, wherein each of the adhesion pads is attached to the chip by epoxy.

8. The package of claim 4, wherein each of the adhesion pads is attached to the chip by tape.

9. The package of claim 4, wherein each of the adhesion pads is attached to the chip by isolation paste.

10. The package of claim 4, wherein at least some leads are electrically coupled with the chip through a conducting wire.

11. The package of claim 4, wherein the isolation material includes epoxy.
